(19) United States
(12) Patent Application Publication
(10) Pub. No.: US 2010/0230691 A1
(43) Pub. Date: Sep. 16, 2010

(54) Ferrous-Metal-Alkaline-Earth-Metal Silicate Mixed Crystal Phosphor and Light Emitting Device using The Same

(76) Inventors: Mitsuhiro Inoue, Aichi-Ken (JP); Akio Namiki, Aichi-ken (JP); Makoto Ishida, Aichi-ken (JP); Takashi Nonogawa, Aichi-ken (JP); Koichi Ota, Aichi-ken (JP); Atsuo Hirano, Aichi-ken (JP); Walter Tews, Greifswald (DE); Gundula Roth, Levenhagen (DE); Stefan Tews, Greifswald (DE)

Correspondence Address: MCGINN INTELLECTUAL PROPERTY LAW GROUP, PLLC, 8321 OLD COURTHOUSE ROAD, SUITE 200, VIENNA, VA, 22182-3817, US

(21) Appl. No.: 12/225,301

(22) PCT Filed: Mar. 26, 2007
(86) PCT No.: PCT/JP2007/057336

§ 371 Date: Nov. 5, 2008

(30) Foreign Application Priority Data
Mar. 27, 2006 (JP) 2006-086314

(51) Int. Cl. H01L 33/50; C09K 11/59; C09K 11/54; C09K 11/67; C09K 11/81; C09K 11/85; C09K 11/84

(52) U.S. Cl. 257/98; 252/301.4 R; 252/301.6 R; 252/301.4 F; 252/301.4 P; 252/301.4 H; 252/301.4 S; 257/E33.055

(57) ABSTRACT

A ferrous-metal-alkaline-earth-metal mixed silicate based phosphor is used in form of a single component or a mixture as a light converter for a primarily visible and/or ultraviolet light emitting device. The phosphor has a rare earth element as an activator. The rare earth element is europium (Eu). Alternatively, the phosphor may have a coactivator formed of a rare earth element and at least one of Mn, Bi, Sn, and Sb.

### TECHNICAL FIELD

The invention relates to a ferrous-metal-alkaline-earth-metal silicate mixed crystal phosphor, which is doped with a rare earth element as an activator, to be available as a light converter for near-ultraviolet and visible light sources, and to a light emitting device using the phosphor.

The present application is based on Japanese patent application No. 2006-086314 filed on Mar. 27, 2006, the entire contents of which are incorporated herein by reference.

### BACKGROUND ART

Luminescent materials to emit green, yellow or red light under excitation with near-ultraviolet or blue light became more and more important over the last few years. The main reason for this is the possibility of using them in light emitting devices as color converters for the production of white light. The most common principle is to use a blue light emitting device with a yellow color converter. The resulting light is white with a relatively low color rendering index. Especially the Cerium activated Garnet Phosphors (WO-A-98-12757, WO-A-02-52615, U.S. Pat. No. 5,998,925, EP-B-1271664 and EP-B-862794) are used in various applications today. Furthermore Garnets are only excitable by blue light and therefore their use is limited to applications based on blue semiconductor chips. Often a primary blue emitting semiconductor chip is combined with more than one phosphor to increase the color rendering (WO-A-00-33389 and WO-A-00-33390). As additional phosphors some inorganic sulphide phosphors (e.g. (Ca, Sr) S:Eu) can be used, but their disadvantage is a leak of stability over the burning time (EP-B-1150361 and U.S. Pat. No. 5,598,059). Furthermore sulphides are very sensitive to moisture and require strictly dry conditions over the whole processing. In WO-A-04-085570 an Europium activated Strontium Oxo-Ortho-Silicate (Sr₃SiO₅:Eu) is used as a light converter in combination with a primary light source emitting blue light at 460 nm for giving white light. Other Silicate based phosphors (Disilicates or Chlorosilicates) are used for the light converters when excited with near-ultraviolet light of about 370 nm to 430 nm in WO-A-02-11214. Furthermore, it is well known that Alkaline Earth Ortho-Silicate phosphors can be used as light converters for white light emitting devices (WO-A-02-11214, WO-A-02-054502 and U.S. Pat. No. 6,255,670). Alkaline Earth Ortho-Silicates show emission colors from the green to the orange region of the optical spectrum. Moreover their use in gas discharge lamps is known from literature (K. H. Butler “Fluorescent Lamp Phosphors” Pennsylvania Univ. Press 1980). In addition, the publication of T. L. Barry (J. Electrochem. Soc., 1968, 1181) has to be cited, where (Ca, Sr, Ba)₂SiO₄:Eu-system homogeneous solid solutions have been systematically investigated. Silicate phosphors on their own or in mixtures are combined with a primary blue or ultraviolet light emitting device to provide better color rendering than the YAG:Ce system.

Alkaline Earth-Ortho-Silicate phosphors show an orthorhombic crystal structure similar to Olivines. This structure can be described by the structure of β-potassium sulfate (β-K₂SO₄). Olivines are all members of the uninterrupted line of solid solutions of (Mg, Fe)₂[SiO₄] between the end members Fayalite (Fe₂[SiO₄] with max. 10% Mg) and Forsterite (Mg₂[SiO₄] with max. 10% Fe). Olivines crystallize orthorhombic, showing mmm-D₂ₕ crystal class structure. The structure can be described as a hexagonal nearly closest packing of Oxygen atoms in the lattice. The Silicon atom is situated in the small tetrahedral voids surrounded by 4 Oxygen atoms. The Mg²⁺ and Fe²⁺ ions occupy to octahedral interstices in the lattice surrounded by 6 Oxygen atoms as closest neighbours. Isotopic crystals to Olivines are Ni₂(SiO₄), CO₂[SiO₄], Alkaline Earth Orthosilicates or Chrysoberyll Al₂[BeO₄]. Olivines form prismatic olive green to yellowish or brownish crystals. The color is formed by impurities of for instance Cr²⁺ or Mn²⁺ or the bonding of crystal water. Olivines themselves are transparent and their crystals show a glasslike gloss. When using absolutely pure starting materials transparent crystals are formed without any coloration. For example, anhydrous Iron (II) Sulfate (FeSO₄) is a white crystalline compound. After re-crystallization from aqueous solution Iron Vitriol (FeSO₄×7H₂O) is formed in green monoclinic prisms.

It is further well known since the 1920s that the luminescence intensity of ZnS phosphors is strongly reduced by doping with small amounts of the iron group element ions Fe²⁺, Ni²⁺ and Co²⁺. Similar observations could be made by introducing Iron group elements into lattices of Halo phosphate phosphors for lamps. Because of it, these elements were termed or named “killers of luminescence” (“Phosphor Handbook” CRC Press LLC, 1999). Therefore normally it is very important to remove such elements in the manufacturing processes of lamp phosphors. Furthermore it is known that the luminescence of Fe³⁺, with a 3d⁵ ground state similar to Mn²⁺, as a common activator ion for fluorescent lamp phosphors and cathode ray tube phosphors, is situated in the wavelength region longer than 670 nm, and only LiAlO₂:Fe³⁺ and LiGaO₂:Fe³⁺ are used for special fluorescent lamp applications.

In U.S. Pat. No. 6,737,681 garnet phosphors are doped in small amounts with several elements and at least one element selected from the group consisting of Pr, Sm, Cu, Ag, Au, Fe, Cr, Nd, Dy, Ni, Ti, Tb and Eu, but in this case Fe is incorporated as a trivalent co-activator for Ce(III).

Patent Literature 1: WO-A-98-12757

Patent Literature 2: WO-A-02-52615

Patent Literature 3: U.S. Pat. No. 5,998,925

Patent Literature 4: EP-B-1271664

Patent Literature 5: EP-B-862794

Patent Literature 6: WO-A-00-33389

Patent Literature 7: WO-A-00-33390

Patent Literature 8: EP-B-1150361

Patent Literature 9: U.S. Pat. No. 5,598,059

Patent Literature 10: WO-A-04-085570

Patent Literature 11: WO-A-02-11214

Patent Literature 12: WO-A-02-054502

Patent Literature 13: U.S. Pat. No. 6,255,670

Nonpatent Literature 1: K. H. Butler “Fluorescent Lamp Phosphors” Pennsylvania Univ. Press 1980

Nonpatent Literature 2: T. L. Barry (Journal of Electrochemical. Society, 1968, 1181

Nonpatent Literature 3: Phosphor Handbook, CRC Press LLC, 1999

### DISCLOSURE OF INVENTION

From the theory in very pure Silicate compounds there should not be any excitability of e.g. Fe in the near ultraviolet or visible region of the optical spectrum. On this account Ferrous Metals should be able for using them as components in the Cation sub-lattice.

The influence of iron group elements as a part of host lattice components in oxygen dominated compounds e.g. silicates activated by rare earth ions like Europium, Terbium and others, has not been described until today. But the ionic radii of bivalent Iron group ions are in a region closed to the radii of Mg²⁺ and Ca²⁺. Therefore it is possible to introduce such elements into silicate host lattices in defined amounts until a rearrangement in the lattice takes place.

Furthermore Europium doped Alkaline Earth Ortho-Silicates show certain sensitivity to all protonic solvents e.g. water and acids which is increased with increasing Barium content. The cause is that Alkaline Earth elements have a highly negative electrochemical redox potential (from −2.87V for Ca to about −2.91V for Ba) and a low electro negativity (1.0 to 1.1). Alkaline Earth hydroxides are strong bases but the Silicic acid is only a very weak acid. That means all above Silicates show more or less hydrolysis when brought into water.

This disadvantage of common Ortho-Silicates should be removed by the introduction of Iron group elements which have a lower negative electrochemical redox potential (−0.45V to −0.26V) and a higher electro negativity (1.6 to 1.8).

An object of the invention is to provide a crystalline mixed silicate based phosphor containing Alkaline Earth and Iron group elements to make them more stable in respect to aqueous conditions or humidity and a light emitting device using the phosphors.

The invention further relates to new luminescent Ferrous-metal Alkaline Earth silicate mixed crystals which after doping with Rare Earth ions show effective luminescence for using them as light converters in blue or near ultraviolet light emitting devices. The invention shall not be limited to Ortho-Silicate compounds. All other silicate crystalline compounds shall also be included.

(1) According to one aspect of the invention, there is provided a ferrous-metal-alkaline-earth-metal mixed silicate based phosphor, wherein:

the phosphor is used in form of a single component or a mixture as a light converter for a primarily visible and/or ultraviolet light emitting device.

In the above invention (1), the following modifications and changes can be made.

(i) The phosphor comprises a rare earth element as an activator.

(ii) The rare earth element comprises europium (Eu).

(iii) The phosphor comprises a coactivator comprising a rare earth element and at least one of Mn, Bi, Sn, and Sb.

(iv) The phosphor is represented by a general formula:

M¹ₐM²_{b}M³_{c}M⁴_{d}(Si_{1-z}M⁵₂)ₑM⁶_{f}M⁷_{g}OₕXₙ:Aₓ

where
M¹=not less than one elements of Ca, Sr, Ba and Zn,
M²=not less than one elements of Mg, Cd, Mn and Be,
M³=not less than one monovalent metal ions of group I elements in the periodic table,
M⁴=not less than one elements of Fe, Co and Ni,
M⁵=not less than one tetravalent elements of Ti, Zr, Hf and Ge,
M⁶=not less than one elements of Al, B, Ga, In, La, Sc and Y,
M⁷=not less than one elements of Sb, P, V, Nb and Ta,
X=not less than one ions of F, Cl, Br and I to balance an electrical charge,
A=not less than one elements of Ce, Pr, Nd, Sm, Eu, Gd, Tb, Dy, Ho, Er, Tm, Yb, Lu, Bi, S, Sn and Sb,
h=a+b+c/2+d+2e+3f/2+5g/2−n/2+x,
0.5≦a≦8,
0≦b≦5,
0≦c≦4,
0<d≦2,
0<e≦10,
0≦f≦2,
0≦g≦2,
0≦n≦4,
0<x≦0.5, and
0≦z≦1.

(v) The phosphor comprises particles a particle diameter of which is all smaller than 50 μm.

(vi) The phosphor is used alone or with an other phosphor as a light converter for an LED to emit light in a visible region of an optical spectrum.

(2) According to another aspect of the invention, a light emitting device comprises:

a light emitting portion;

a wavelength conversion portion comprising a ferrous-metal-alkaline-earth-metal mixed silicate based phosphor to wavelength-convert a light emitted from the light emitting portion;

a power-supply portion to supply an electrical power to the light emitting portion; and

a sealing portion sealing the light emitting portion and the power-supply portion.

In the above invention (2), the following modifications and changes can be made.

(vii) The light emitting portion comprises a semiconductor light emitting element, and

the ferrous-metal-alkaline-earth-metal mixed silicate based phosphor is represented by a general formula:

M¹ₐM²_{b}M³_{c}M⁴_{d}(Si_{1-z}M⁵_{z})ₑM⁶_{f}M⁷_{g}OₕXₙ:Aₓ

where
M¹=not less than one elements of Ca, Sr, Ba and Zn,
M²=not less than one elements of Mg, Cd, Mn and Be,
M³=not less than one monovalent metal ions of group I elements in the periodic table,
M⁴=not less than one elements of Fe, Co and Ni,
M⁵=not less than one tetravalent elements of Ti, Zr, Hf and Ge,
M⁶=not less than one elements of Al, B, Ga, In, La, Sc and Y,
M⁷=not less than one elements of Sb, P, V, Nb and Ta,
X=not less than one ions of F, Cl, Br and I to balance an electrical charge,
A=not less than one elements of Ce, Pr, Nd, Sm, Eu, Gd, Tb, Dy, Ho, Er, Tm, Yb, Lu, Bi, S, Sn and Sb,
h=a+b+c/2+d+2e+3f/2+5g/2−n/2+x,
0.5≦a≦8,
0≦b≦5,
0≦c≦4,
0<d≦2,
0<e≦10,
0≦f≦2,
0≦g≦2,
0≦n≦4,
0<x≦0.5, and
0≦z≦1.

(viii) The light emitting portion comprises a group III nitride-based compound semiconductor light emitting element, and

the ferrous-metal-alkaline-earth-metal mixed silicate based phosphor is represented by a general formula:

M¹ₐM²_{b}M³_{c}M⁴_{d}(Si_{1-z}M⁶_{z})ₑM⁷_{g}OₕXₙ:Aₓ

where
M¹=not less than one elements of Ca, Sr, Ba and Zn,
M²=not less than one elements of Mg, Cd, Mn and Be,
M³=not less than one monovalent metal ions of group I elements in the periodic table,
M⁴=not less than one elements of Fe, Co and Ni,
M⁵=not less than one tetravalent elements of Ti, Zr, Hf and Ge,
M⁶=not less than one elements of Al, B, Ga, In, La, Sc and Y,
M⁷=not less than one elements of Sb, P, V, Nb and Ta,
X=not less than one ions of F, Cl, Br and I to balance an electrical charge,
A=not less than one elements of Ce, Pr, Nd, Sm, Eu, Gd, Tb, Dy, Ho, Er, Tm, Yb, Lu, Bi, S, Sn and Sb,
h=a+b+c/2+d+2e+3f/2+5g/2−n/2+x,
0.5≦a≦8,
0<b≦5,
0≦c≦4,
0<d≦2,
0<e≦10,
0≦f≦2,
0≦g≦2,
0≦n≦4,
0<x≦0.5, and
0≦z≦1.

(ix) The wavelength conversion portion is mixed with a light transmitting material and is disposed in the sealing portion in form of a layer.

(x) The wavelength conversion portion is mixed with a light transmitting material and is disposed in a vicinity of the light emitting portion.

(xi) The light emitting portion comprises:

a group III nitride-based compound semiconductor light emitting element;

an element mounting substrate mounting the light emitting element; and

a glass sealing portion integrally sealing the light emitting element and the element mounting substrate.

(xii) The wavelength conversion portion is integrally disposed on a surface of the glass sealing portion.

(xiii) The semiconductor light emitting element comprises a sapphire substrate shaped optically.

### ADVANTAGES OF THE INVENTION

Owing to sensitivity to protonic solvents of general Alkaline Earth silicate based phosphors, Iron group elements, when incorporated into the lattice, increase the stability to water strongly which is caused by the less negative electrochemical potentials of Iron, Cobalt and Nickel compared to Alkaline Earth elements, e.g., strontium. A washing procedure with water should not affect the crystal surface quality on a large scale. Use of the phosphors to a light emitting device can realize a light emitting device having not only a good conversion property, but also an excellent resistance to humidity and water.

### BRIEF DESCRIPTION OF DRAWINGS

The preferred embodiments according to the invention will be explained below referring to the drawings, wherein:

FIG. 1 is a cross-sectional view showing a light emitting device in a second preferred embodiment according to the invention;

FIG. 2 is a longitudinal cross-sectional view showing a light emitting element used to a light emitting device of the second preferred embodiment according to the invention;

FIG. 3 is a cross-sectional view showing a light emitting device in a third preferred embodiment according to the invention;

FIG. 4 is a cross-sectional view showing a light emitting device in a fourth preferred embodiment according to the invention;

FIG. 5 is a longitudinal cross-sectional view showing the light emitting element of flip mounting-type of the fourth preferred embodiment according to the invention;

FIG. 6 is a cross-sectional view showing a light emitting device in a fifth preferred embodiment according to the invention;

FIG. 7 is a longitudinal cross-sectional view showing a light emitting element shaped to facilitate light extraction from inside thereof;

FIG. 8 is a longitudinal cross-sectional view showing another light emitting element fabricated to facilitate light extraction from inside thereof;

FIG. 9 is a cross-sectional view showing a light emitting device in a sixth preferred embodiment according to the invention;

FIG. 10 is a cross-sectional view showing a light emitting device in a seventh preferred embodiment according to the invention; and

FIG. 11 is a cross-sectional view showing a light emitting device in an eighth preferred embodiment according to the invention.

### BEST MODE FOR CARRYING OUT THE INVENTION

### First Embodiment

Some of the new luminous materials according to the invention are shown in table 1. Luminescence data are compared to pure Alkaline Earth Silicates doped with Rare Earth elements.

TABLE 1

| | Relative optical properties | | |
|---|---|---|---|
| | | Emission | |
| | | maximum | Fe, Co |
| | | without Fe, | and/or Ni |
| | Luminous | Co and/or | containing |
| Composition of Ferrous metal containing Silicates | intensity | Ni | Silicates |
| (Ba_{0.177}Sr_{0.799}Ca_{0.001}Fe_{0.003}Eu_{0.02})₂SiO₄ | 100.8% | 565.0 nm | 563.0 nm |
| (Ba_{0.3525}Sr_{0.625}Co_{0.0025}Eu_{0.02})₂SiO₄ | 99.7% | 533.0 nm | 531.5 nm |
| (Ba_{0.222}Sr_{0.7455}Ni_{0.0025}Eu_{0.03})₂SiO₄ | 100.2% | 560.0 nm | 557.5 nm |
| (Ba_{0.897}Sr_{0.05}Fe_{0.05}Eu_{0.003})₂Si(Al_{0.0001})O_{4.00015} | 101.7% | 508.5 nm | 507.0 nm |
| (Ba_{0.97}Eu_{0.03})₃(Mg_{0.9}Fe_{0.1})Si₂O₈ | 100.5% | 437.0 nm | 436.5 nm |
| (Ba_{0.95}Sr_{0.02}Eu_{0.03})₃(Mg_{0.9475}Fe_{0.05}Co_{0.0025})(Si_{0.99}Ge_{0.01})₂O₈ | 100.5% | 437.5 nm | 437.0 nm |
| (Ba_{0.67}Sr_{0.31}Eu_{0.02})₃(Mg_{0.81}Fe_{0.07}Mn_{0.12})Si₂O₈ | 101.3% | 639.5 nm | 643.0 nm |
| (Ba_{0.919}Fe_{0.03}Ni_{0.001}Eu_{0.05}Dy_{0.0002})(Si_{0.98}Ge_{0.02})₂O_{5.0003} | 102.1% | 521.0 nm | 519.5 nm |
| (Ba_{0.0015}Sr_{0.951}Ca_{0.001}Fe_{0.015}Ni_{0.0015}Eu_{0.03})₃SiO₅ | 100.7% | 575.0 nm | 572.5 nm |
| (Ba_{0.96}Eu_{0.04})₂(Mg_{0.82}Fe_{0.08}Zn_{0.1})Si₂O₇ | 100.2% | 513.0 nm | 511.5 nm |

In general, starting materials, e.g. Alkaline Earth carbonates, Silica (SiO₂), Europium oxide (Eu₂O₃), Iron oxide (Fe₂O₃) or Iron chloride (FeCl₃), Cobalt chloride (CoCl₂), Nickel chloride (NiCl₂) or Nickel hydroxide carbonate (NiCO₃×2Ni(OH)₂), fluxing agent (NH₄Cl) and others are stoichiometrically mixed for a period of 2-8 hours. The mixture is firstly dried in a drying furnace at 150-200° C. for 2-12 hours. Afterwards the dried mixture is pre-fired under Nitrogen in a Corundum crucible at 600-800° C. for 4-8 hours. After cooling to room temperature the mixture is grinded again and finally fired at 1200-1400° C. for 6-12 hours under a reducing atmosphere of Nitrogen/Hydrogen. It is recommended to fire below 1380° C. Otherwise glassy phases are formed resulting in a strongly decreases of the efficiency of the final phosphors. The raw phosphor cake will be crushed and then additionally grinded. The rough phosphor is washed and dried at 100-150° C. for 8-10 hours and finally sieved.

Hereinafter, ferrous-metal-alkaline-earth-metal silicate mixed crystal phosphors of the first preferred embodiment will be explained in detail.

### Phosphor 1: (Ba_{0.177}Sr_{0.799}Ca_{0.001}Fe_{0.003}Eu_{0.02})₂SiO₄

For producing 4 Mol of phosphor 279.48 g of BaCO₃, 943.71 g of SrCO₃, 0.8 g of CaCO₃, 1.92 g of Fe₂O₃, 28.16 g of Eu₂O₃, 240.35 g of dried SiO₂ and 13.37 g NH₄Cl as fluxing agent were weighted and mixed for 5 hours. This starting mixture is filled into a glass dish and dried at 175° C. for 8 hours. The dried mixture is filled into crucibles and fired for a first period at 650° C. for 3 hours.

After cooling to room temperature the mixture is grinded again and after this a second firing process under a reducing atmosphere (10 Vol % H₂ in N₂) at 1250° C. for 12 hours has been carried out. The rough phosphor cake is crushed, then well grinded and washed with water. After separation, the Silicate material is dried at 130° C. and finally sieved.

Measuring of the optical properties of the produced phosphor resulted in a broad emission band with a maximum at 563.0 nm (450 nm excitation) and excitability over the range from 250 to 500 nm. The brightness amounted to 100.8% compared with the pure Silicate phosphor without Fe.

### Phosphor 2: (Ba_{0.3525}Sr_{0.625}Co_{0.0025}Eu_{0.02})₂SiO₄

For the preparation of 4 Mol phosphor 556.58 g of BaCO₃, 738.20 g of SrCO₃, 2.59 g of CoCl₂, 28.16 g of Eu₂O₃, 240.35 g of dried SiO₂ and 13.37 g NH₄Cl as fluxing agent were weighted and mixed for 6 hours. This starting mixture is filled into a glass dish and dried at 175° C. for 8 hours. The dried mixture is filled into crucibles and fired for a first period at 650° C. for 5 hours. After cooling to room temperature the mixture is grinded a second time then filled into Corundum crucibles and fired for a second period under a reducing atmosphere (10 Vol % H₂ in N₂) at 1250° C. for 14 hours. The rough phosphor cake is crushed, then well grinded and washed with water. After separation, the Silicate material is dried at 130° C. and finally sieved.

Measuring of the optical properties of the produced phosphor resulted in a broad emission band with a maximum at 531.5 nm and excitability over the range from 250 to 480 nm. The brightness amounted to 99.7% compared with the pure Silicate phosphor without Co.

### Phosphor 3: (Ba_{0.67}Sr_{0.31}Eu_{0.02})₃(Mg_{0.81}Fe_{0.07}Mn_{0.12})Si₂O₈

For the preparation of 2 Mol phosphor 793.43 g of BaCO₃, 274.61 g of SrCO₃, 136.58 g of MgCO₃, 17.03 g of MnO, 11.18 g of Fe₂O₃, 21.12 g of Eu₂O₃, 240.36 g of dried SiO₂ and 8.56 g NH₄Cl as fluxing agent were weighted and mixed for 6 hours. The starting mixture is filled into a glass dish and dried at 175° C. for 10 hours. The dried composition is filled into crucibles and fired for a first period at 650° C. for 6 hours. After cooling to room temperature the mixture is grinded a second time and after this filled into Corundum crucibles and fired for a second period under a reducing atmosphere (10 Vol % H₂ in N₂) at 1300° C. for 10 hours. The rough phosphor cake is crushed, then well grinded and washed with water. After separation, the Silicate material is dried at 130° C. and finally sieved.

Measuring of the optical properties of the produced phosphor resulted in a broad emission band with a maximum at about 643.0 nm and excitability over the range from 250 to 410 nm. The brightness amounted to 101.3% compared with the pure Silicate phosphor without Fe.

### Phosphor 4: (Ba_{0.222}Sr_{0.7455}Ni_{0.0025}Eu_{0.03})₂SiO₄

For the preparation of 4 Mol phosphor 350.53 g of BaCO₃, 880.52 g of SrCO₃, 2.59 g of NiCl₂, 42.24 g of Eu₂O₃, 240.36 g of dried SiO₂ and 18.54 g NH₄Cl as fluxing agent were weighted and mixed for 5 hours. The ready starting mixture is filled into a glass dish and dried at 175° C. for 8 hours. The dried composition is filled into crucibles and fired for a first period at 650° C. for 8 hours. After cooling to room temperature the mixture is grinded a second time and then filled into Corundum crucibles and fired for a second period under a reducing atmosphere (10 Vol % H₂ in N₂) at 1250° C. for 15 hours. The rough phosphor cake is crushed, then well grinded and washed with water. After separation, the Silicate material is dried at 130° C. and finally sieved.

Measuring of the optical properties of the produced phosphor resulted in a broad emission band with a maximum at 557.5 nm and excitability over the range from 250 to 490 nm. The brightness amounted to 100.2% compared with the pure Silicate phosphor without Ni.

### Advantages of the First Embodiment

Concerning the improved stability properties to water or humidity in all above cases a general improvement could be observed. After a thermal treatment (10 h, 85° C.) of the final phosphor in air containing 80% humidity the maintenance of the brightness was much better than in case of pure Alkaline Earth Silicate phosphors and amounted to about 105%-110%.

By using the phosphors described above to a light conversion portion of a light emitting device, a wavelength converted light with desired color, the light being stable to humidity can be efficiently obtained. Further, by using a light emitting element to a light source, a light emitting device being bright for small size can be obtained.

### Second Embodiment

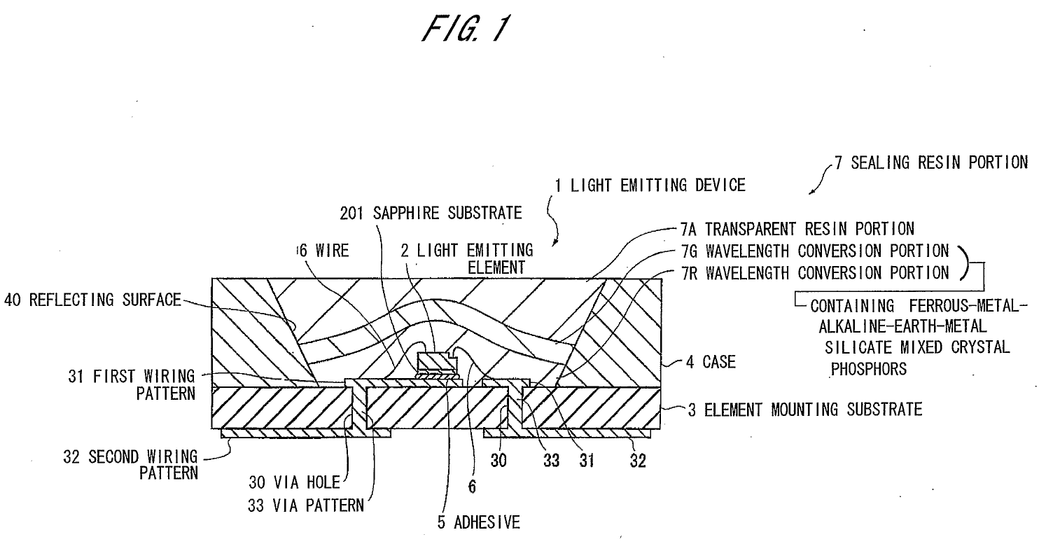

FIG. 1 is a cross-sectional view showing a light emitting device of the second preferred embodiment according to the invention.

The light emitting device 1 comprises a light emitting element 2 comprising semiconductor layers (GaN-type semiconductor layers) comprising nitride based semiconductor compounds as a light emitting portion, a element mounting substrate 3 mounting the light emitting element 2 thereon and electrically connected to outside, a case 4 formed integrally with the element mounting substrate 3, comprising a reflecting surface 40 with a slope in the inner surface, an adhesive 5 fixing the light emitting element 2 on the element mounting substrate 3, a wire 6 comprising Au, electrically connecting electrodes of the light emitting element 2 and a first wiring pattern 31 formed on the element mounting substrate 3 as an electrical power supply, and a sealing resin portion 7 comprising a wavelength conversion portion 7R sealing the light emitting element 2 fixed to the inner side of the case 4, the portion 7R comprising a red phosphor comprising the ferrous-metal-alkaline-earth-metal silicate mixed crystal phosphor explained in the first preferred embodiment, a wavelength conversion portion 7G comprising a green phosphor, and a transparent resin portion 7A being colorless and transparent, formed as an upper layer than the wavelength conversion portion 7B.

The light emitting element 2 is formed on a sapphire substrate 201 by a crystal growth of a GaN-based semiconductor layer based on MOCVD (Metal Organic Chemical Vapor Deposition) method, in the first preferred embodiment the element 2 emits a blue light having a peak wavelength of 460 to 465 nm.

The element mounting substrate 3 comprises ceramics with a good workability, and comprises via holes 30 formed by passing through from the front surface to the back surface of the substrate, a first wiring pattern 31 formed on the front surface by a patterning with an electrically conductive paste such as tungsten (W), a second wiring pattern 32 similarly formed on the back surface to be a mounting surface by a patterning with an electrically conductive paste and via patterns 33 electrically connecting the first wiring pattern 31 and the second wiring pattern 32. In the preferred embodiment, the element mounting substrate comprises a ceramic substrate of Al₂O₃, but a ceramic substrate comprising a good emission performance such as AlN can be also used.

The case 4 comprises a resin material such as nylon, attached to the element mounting substrate 3 integrally. The case inner surface comprises the reflecting surface 40 with a slope so as to reflect a light emitted from the light emitting element 2 in a light emission direction, and the inner surface is formed circularly. Further, the case 4 can be also formed of the ceramics such as Al₂O₃ described above.

The adhesive 5 comprises a thermally-conductive Ag paste, the light emitting element 2 is bonded and fixed onto the first wiring pattern 31 therewith, and heat generation due to a light emission of the light emitting element 2 is thermally-conducted to the first wiring pattern 31 therethrough.

The sealing resin portion 7 comprises the wavelength conversion portion 7R formed by mixing silicone and (Ba_{0.67}Sr_{0.31}Eu_{0.02})₃(Mg_{0.81}Fe_{0.07}Mn_{0.12}) Si₂O₈ being a ferrous-metal-alkaline-earth-metal silicate mixed crystal phosphor as a phosphor emitting a red light, and the portion 7 is disposed in a neighborhood of the light emitting element 2. The red phosphor of the wavelength conversion portion 7R emits a red light having a peak wavelength of 643 nm when excited by the blue light emitted from the light emitting element 2.

Further, the sealing resin portion 7 comprises the wavelength conversion portion 7G formed by mixing epoxy resin and (Ba_{0.177}Sr_{0.799}Ca_{0.001}Fe_{0.003}Eu_{0.02})₂SiO₄ being a ferrous-metal-alkaline-earth-metal silicate mixed crystal phosphor as a phosphor emitting a green light, and the portion 7 is disposed as an upper layer than the wavelength conversion portion 7R. The green phosphor of the wavelength conversion portion 7G emits a green light having a peak wavelength of 563 nm when excited by the blue light emitted from the light emitting element 2. The transparent resin portion 7A comprising epoxy resin, and being colorless and transparent is formed on the surface of the wavelength conversion portion 7G. Further, instead of epoxy resin, silicone can be also used as the resin material constituting the sealing resin portion 7.

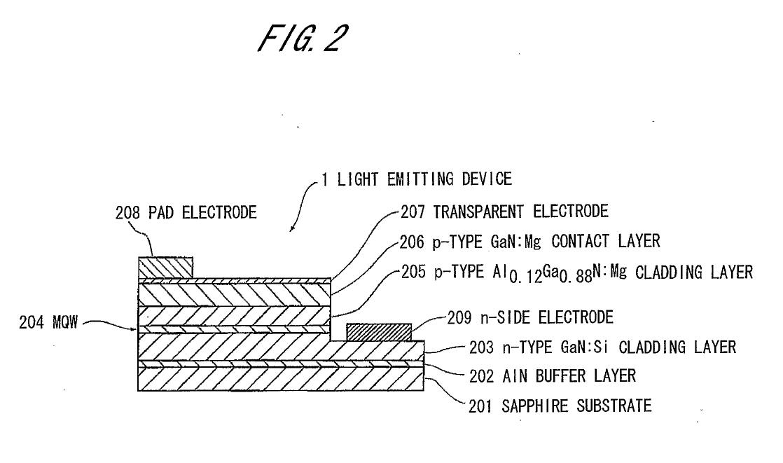

FIG. 2 is a longitudinal cross-sectional view showing a light emitting element used to a light emitting device of the second preferred embodiment according to the invention.

The light emitting element 2 is a horizontal light emitting element where p-side and n-side electrodes are disposed in a horizontal direction, and is formed by a sequentially multi-layered structure, the structure comprising a sapphire substrate 201 being a growth substrate for growing III group nitride based compounds thereon, a AlN buffer layer 202 formed on the sapphire substrate 201, a n-type GaN:Si cladding layer 203 doped with Si, a MQW 204 having a multiquantum well structure of InGaN/GaN, a p-type Al_{0.12}Ga_{0.88}N:Mg cladding layer 205 doped with Mg, a p-type GaN:Mg contact layer 206 doped with Mg, and a transparent electrode 207 comprising ITO (Indium Tin Oxide) and diffusing electrical current to the p-type GaN:Mg contact layer 206, and from the AlN buffer layer 202 to the p-type GaN:Mg contact layer 206 are formed by the MOCVD (Metal Organic Chemical Vapor Deposition) method.

Further, a pad electrode 208 comprising Au is formed on a surface of the transparent electrode 207, and a n-side electrode 209 comprising Al is formed on the n-type GaN:Si cladding layer 203 where from the p-type GaN:Mg contact layer 206 to the n-type GaN:Si cladding layer 203 in the light emitting element portion are eliminated by etching process.

The AlN buffer layer 202 is formed by using H₂ as a carrier gas and supplying trimethylgallium (TMG) and trimethylaluminum (TMA) to a reactor in which the sapphire substrate 201 is disposed.

The n-type GaN:Si cladding layer 203 is formed by using N₂ as a carrier gas, supplying NH₃ and trimethylgallium (TMG) to a reactor in which the sapphire substrate 201 is disposed, and using monosilane (SiH₄) as a dopant for providing n-type conductive property and as Si material, so as to be formed on the AlN buffer layer 202 to a thickness of about 4 μm.

The MQW 204 is formed by using H₂ as a carrier gas and supplying trimethylindium (TMI) and TMG to a reactor. When InGaN well layer is formed, TMI and TMG are supplied, and when GaN barrier layer is formed, TMG is supplied. In the preferred embodiment, InGaN well layer and GaN barrier layer of the MQW 204 are formed in 4 pairs, but they can be formed in 3 to 6 pairs.

The p-type Al_{0.12}Ga_{0.88}N:Mg cladding layer 205 is formed by using N₂ as a carrier gas, supplying NH₃, TMG, TMA and Cp₂Mg as Mg material to a reactor in which the sapphire substrate 201 is disposed.

The p-type GaN:Mg contact layer 206 is formed by using N₂ as a carrier gas, supplying NH₃, TMG, and Cp₂Mg as Mg material to a reactor in which the sapphire substrate 201 is disposed.

The light emitting device 1 emits a blue light having a peak wavelength of 460 to 465 nm, when an electrical power is supplied to the light emitting device 1 from outside through the second wiring pattern 32, so as to produce an electron-positive hole recombination in the InGaN well layer in the MQW 204 of the light emitting element 2. The blue light enters the wavelength conversion portion 7R of the sealing resin portion 7 to excite a red phosphor of the wavelength conversion portion 7R, so as to produce a red light having a peak wavelength of 643 nm. Further, the blue light which has past through the wavelength conversion portion 7R enters the wavelength conversion portion 7G to excite a green phosphor of the wavelength conversion portion 7G, so as to produce a green light having a peak wavelength of 563 nm. The red light and the green light emitted as described above and the blue light emitted from the light emitting element 2 are mixed together, so that a white light is produced and emitted in the light emission direction.

### Advantages of the Second Embodiment

According to the second preferred embodiment described above, the wavelength conversion portion 7R and the wavelength conversion portion 7G are excited by the blue light which is an excitation wavelength band of ferrous-metal-alkaline-earth-metal silicate mixed crystal phosphors, so that a white light having a good color rendering property and color reproducibility can be obtained and a light emitting device in which the phosphor is less subject to deterioration by humidity can be obtained.

In the case of the light emitting device 1 of surface-mounted-type shown in FIG. 1, if absorption of humidity in the sealing resin portion 7 and absorption of humidity due to decrease in adhesion between the case 4 and the sealing resin portion 7 are caused, it is considered that deterioration of the phosphor is produced, but in the light emitting device 1 of the second preferred embodiment described above, ferrous-metal-alkaline-earth-metal silicate mixed crystal phosphors improved in humidity resistance is used, so that decrease in the light emitting properties by the absorption of humidity can be prevented in comparison with conventional silicate phosphors, and a light emitting device can be provided, in which the phosphor is less subject to deterioration by the absorption of humidity even in use under high humidity environment.

Further, in the second preferred embodiment the light emitting device 1 using (Ba_{0.16}Sr_{0.799}Ca_{0.001}Fe_{0.02}Eu_{0.02})₂SiO₄ as yellow phosphor has been explained, but (Ba_{0.3525}Sr_{0.625}Co_{0.0025}Eu_{0.02})₂SiO₄, (Ba_{0.222}Sr_{0.7455}Ni_{0.0025}Eu_{0.03})₂SiO₄, (Ba_{0.897}Sr_{0.05}Fe_{0.05}Eu_{0.003})₂Si(Al_{0.0001})O_{4.00015}, (Ba_{0.96}Eu_{0.04})₂(Mg_{0.82}Fe_{0.08}Zn_{0.1})Si₂O₇, can be also used as other ferrous-metal-alkaline-earth-metal silicate mixed crystal green phosphors.

Furthermore, in the second preferred embodiment a structure comprising a piece of the light emitting element 2 has been explained, but the light emitting device 1 comprising a plurality of the light emitting elements 2 can be also used. Further, colors of the lights obtained by the wavelength conversion are not particularly limited in the white color described above, but lights of colors based on a mixture of the emission colors and the lights emitted from the phosphors can be also used.

### Third Embodiment

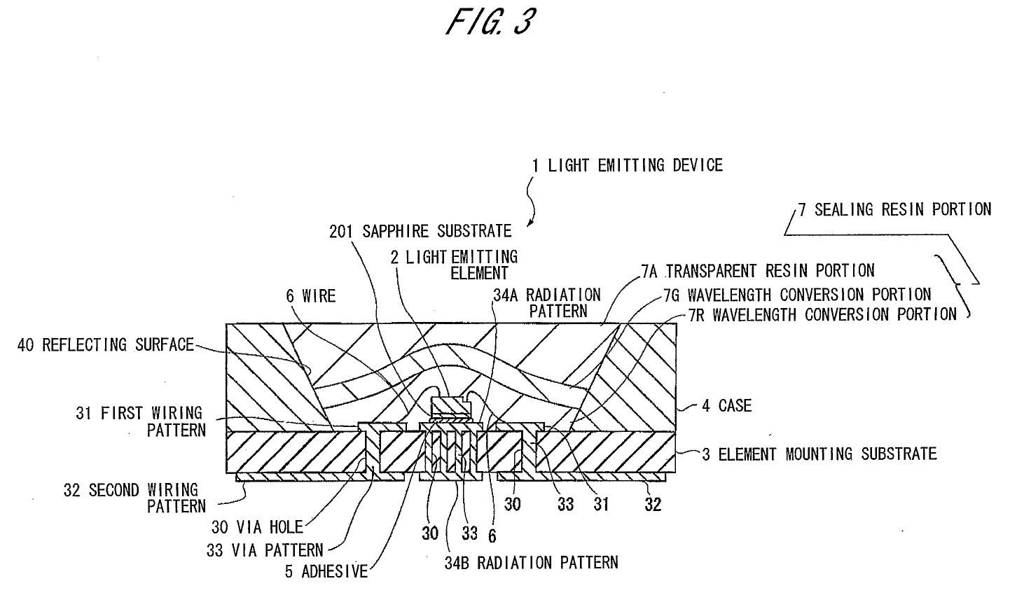

FIG. 3 is a cross-sectional view showing a light emitting device of the third preferred embodiment according to the invention. In the explanation described below, as to the same structural and functional portions as in the second preferred embodiment, the same references are used.

The light emitting device 1 is different from the device of the second preferred embodiment in that the device 1 comprises an emission path formed by that an emission pattern 34A is formed just below the light emitting element 2 explained in the second preferred embodiment with an electrically conductive paste, and the emission pattern 34A is connected to an emission pattern 34B formed in the back surface side of the substrate through the via patterns 33.

### Advantages of the Third Embodiment

According to the third preferred embodiment described above, in addition to the preferred advantages of the second preferred embodiment, heat caused by the emission of the light emitting element 2 is conducted to the back surface side of the substrate through the emission patterns 34A, 34B, and the via patterns 33, so that heat expansion of the sealing resin portion 7 can be decreased and occurrence of package cracks and the like can be inhibited.

### Fourth Embodiment

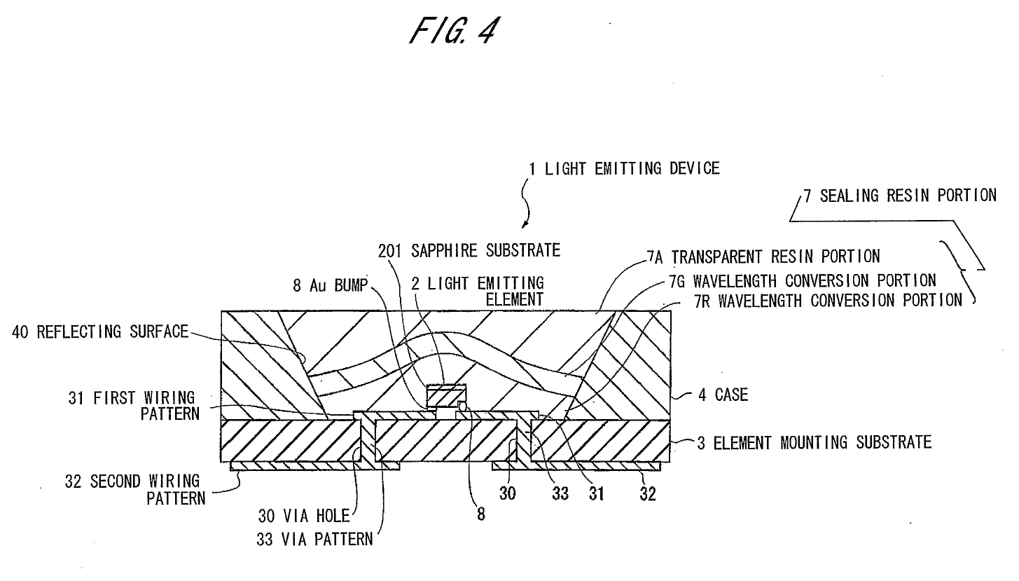

FIG. 4 is a cross-sectional view showing a light emitting device of the fourth preferred embodiment according to the invention.

The light emitting device 1 is different from the device of the third preferred embodiment in a structure that instead of the light emitting element 2 of face-up type explained in the third preferred embodiment the light emitting element 2 of flip mounting-type where the Sapphire substrate 201 is disposed in the light taking out side is used, and the electrode of the light emitting element 2 is electrically connected to the first wiring pattern 31 through a Au bump 8.

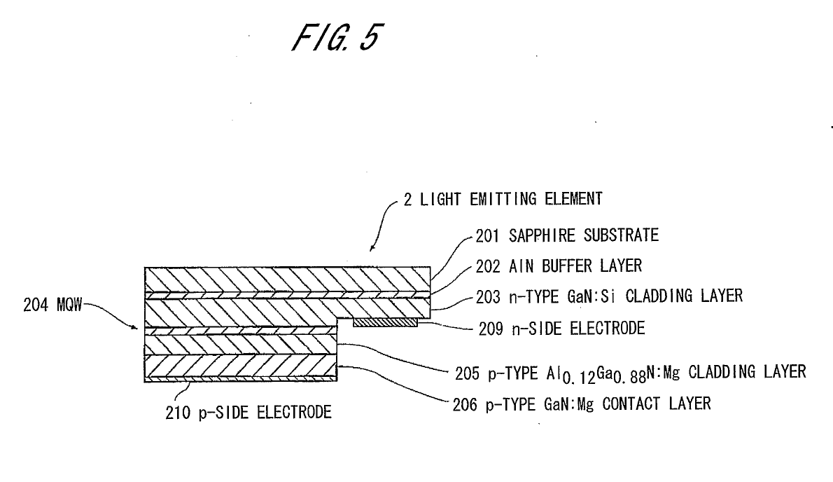

FIG. 5 is a longitudinal cross-sectional view showing the light emitting element of flip mounting-type of the fourth preferred embodiment according to the invention.

The light emitting element 2 is formed by using rhodium (Rh) as the p-side electrode 210 and aluminum (Al) as the n-side electrode 209. Further, ITO can be also used as the p-side electrode 210.

### Advantages of the Fourth Embodiment

According to the fourth preferred embodiment described above, in addition to the preferred advantages of the third preferred embodiment, a wire bonding step can be omitted and mass productivity can be improved, and by setting a light taking out surface to the side of the element mounting substrate 3 the taking light-efficiency can be enhanced.

### Fifth Embodiment

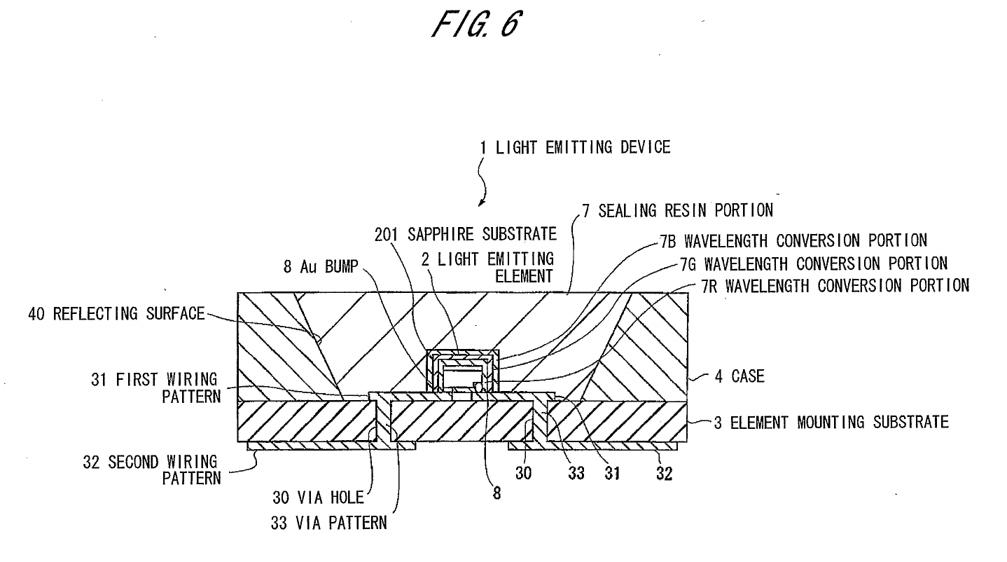

FIG. 6 is a cross-sectional view showing a light emitting device of the fifth preferred embodiment according to the invention.

The light emitting device 1 is different from the device of the fourth preferred embodiment in a structure that the light emitting device 1 comprises a light emitting element 2 emitting a near-ultraviolet light having the emission wavelength of 380 nm as the light emitting element 2 explained in the fourth preferred embodiment, and the wavelength conversion portions 7R, 7G and 7B containing ferrous-metal-alkaline-earth-metal silicate mixed crystal phosphors to be excited by the near-ultraviolet light are formed around the element 2 in a thin film-shape.

The wavelength conversion portion 7R contains (Ba_{0.67}Sr_{0.31}Eu_{0.02})₃(Mg_{0.81}Fe_{0.07}Mn_{0.12})Si₂O₈ as the red phosphor in silicone as a binder, the wavelength conversion portion 7G contains (Ba_{0.177}Sr_{0.799}Ca_{0.001}Fe_{0.003}Eu_{0.02})₂SiO₄ in silicone as a binder similarly to the wavelength conversion portion 7R, and the wavelength conversion portion 7G contains (Ba_{0.97}Eu_{0.03})₃(Mg_{0.9}Fe_{0.1})Si₂O₈ in silicone as a binder similarly to the wavelength conversion portions 7R, 7G.

### Advantages of the Fifth Embodiment

According to the fifth preferred embodiment described above, in addition to the preferred advantages of the fourth preferred embodiment, the wavelength conversion portions 7R, 7G and 7B are formed in a neighborhood of the light emitting element 2, so that a point light source capable of emitting a white light from a neighborhood of the light emitting element 2 can be obtained. The point light source is better adapted to applications which need beam lights with small diameter.

Further, in the fifth preferred embodiment a structure that the wavelength conversion portions of RGB 7R, 7G and 7B are formed in a neighborhood of the light emitting element 2 to emit the near ultraviolet light has been explained, but the phosphors contained in the wavelength conversion portions 7R, 7G and 7B can be also excited by the blue light having a peak wavelength of 460 to 465 nm emitted from the light emitting element 2 to emit the blue light as explained in the second preferred embodiment. In this case, the composition of the wavelength conversion portion 7B can be omitted and epoxy resin can be used for a binder used in the wavelength conversion portions. However, in a case that a blue light emitting element 2 comprising a large light emitting intensity is used, it is preferable to use silicone in consideration of deterioration by light.

Further, in a case that the blue light emitting element 2 is used, the wavelength conversion portions containing a yellow phosphor can be formed in a neighborhood of the light emitting element. In the case, (Ba_{0.0015}Sr_{0.951}Ca_{0.001}Fe_{0.015}Ni_{0.0015}Eu_{0.03})₃SiO₅ as ferrous-metal-alkaline-earth-metal silicate mixed crystal phosphors can be used as the yellow phosphor.

Further, in a structure that the wavelength conversion portion containing a yellow phosphor is formed, if color rendering property of a white color is needed to be enhanced, a wavelength conversion portion containing (Ba_{0.67}Sr_{0.31}Eu_{0.02})₃(Mg_{0.81}Fe_{0.07}Mn_{0.12})Si₂O₈ of a red phosphor in addition to the (Ba_{0.0015}Sr_{0.951}Ca_{0.001}Fe_{0.015}Ni_{0.0015}Eu_{0.03})₃SiO₅ described above can be formed, or a wavelength conversion portion containing the red phosphor can be formed on the wavelength conversion portion containing the yellow phosphor by lamination.

Further, in a case that the light emitting element of flip mounting-type is used, the sapphire substrate 201 is worked in shape by cutting, etching, etc., so that interfacial reflection due to refractive index difference from the sealing resin portion 7 can be inhibited.

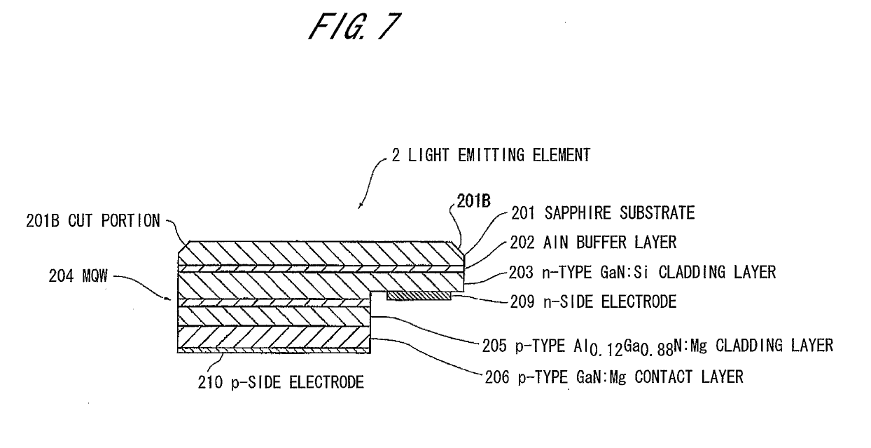

FIG. 7 is a longitudinal cross-sectional view showing a light emitting element shaped to facilitate light extraction from inside thereof.

The light emitting element 2 is structured such that the sapphire substrate 201 of the light emitting element 2 explained in FIG. 5 has a cut portion 201B formed by cutting an edge of the substrate 201 at an angle of 45 degrees to allow the light being transversely transmitted inside the light emitting element 2 to be extracted to outside through the cut portion 201B. By the structure, light loss can be reduced which may be caused by that light totally reflected at the interface between the light emitting element and the sealing resin portion 7 is confined inside the light emitting element.

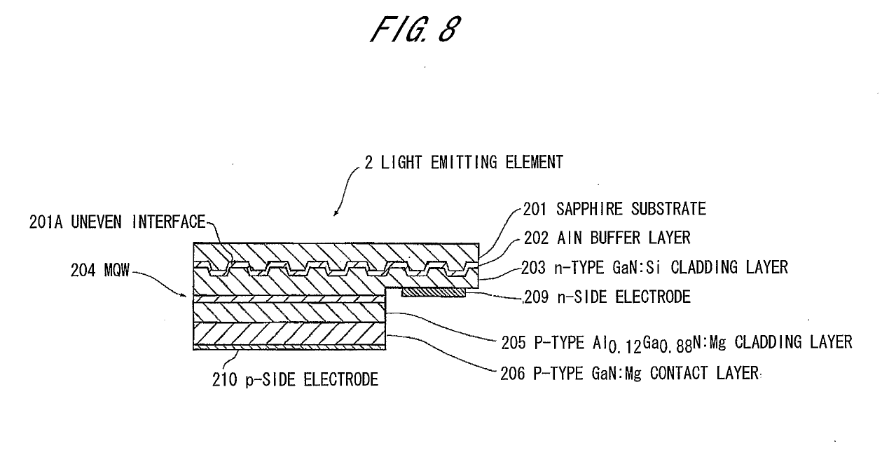

FIG. 8 is a longitudinal cross-sectional view showing another light emitting element fabricated to facilitate light extraction from inside thereof.

The light emitting element 2 has an uneven interface 210A with concavities and convexities, each of the convexities being shaped trapezoidal, formed between the sapphire substrate 201 of the light emitting element 2 explained in FIG. 5 and the n-type GaN:Si cladding layer 203 including the AlN buffer layer 202, so that light emitted from the InGaN layer of the MQW 204 can be radiated outside more in amount by changing the path of light by the concavities and convexities. By the structure, a returning light toward inside of the light emitting element 2 caused by the total reflection can be reduced, and external emission efficiency can be increased.

### Sixth Embodiment

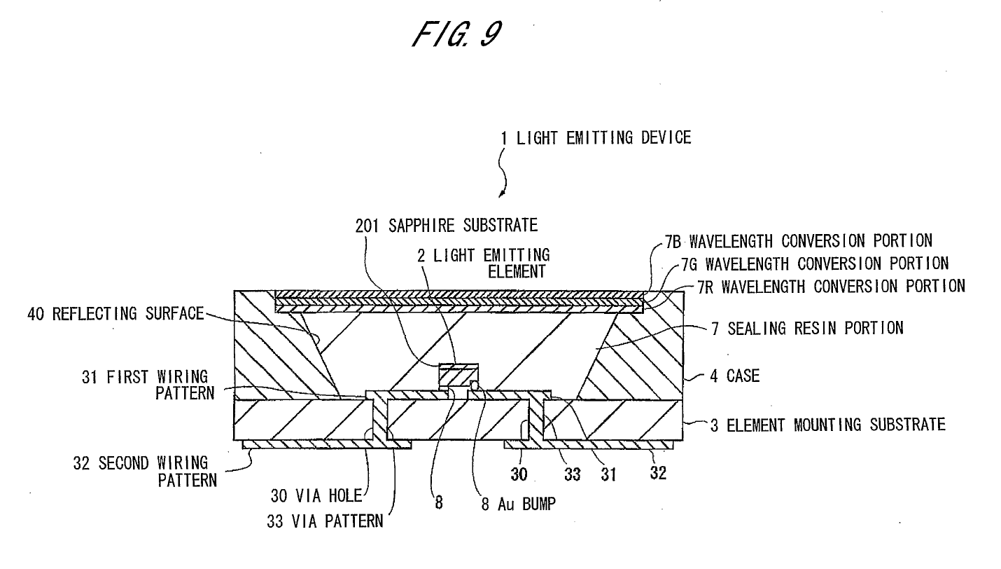

FIG. 9 is a cross-sectional view showing a light emitting device of the sixth preferred embodiment according to the invention.

The light emitting device 1 is different from the device of the first preferred embodiment in a structure that instead of the light emitting element 2 to emit a blue light explained in the second preferred embodiment a light emitting element 2 of flip-tip type to emit the near ultraviolet light of 380 nm is used as a light source, and the wavelength conversion portions 7R, 7G and 7B are formed in the light taking out portion of the case 4 by lamination of thin-film shape, so that a white color can be taken out based on the mixture of a red color, a green color and a blue color obtained by the wavelength conversion portions. An empty space between the wavelength conversion portion 7R and an element fixing surface on which the light emitting element 2 is fixed, is sealed with the sealing resin portion 7 comprising silicone.

### Advantages of the Sixth Embodiment

According to the sixth preferred embodiment described above, the wavelength conversion portions 7R, 7G and 7B are formed in the light taking out portion of the case 4 in thin-film shape, so that the phosphors usage is inhibited but wavelength conversion property is excellent, and a white color based on the mixture of the wavelength conversion lights of a red color, a green color and a blue color can be obtained.

Further, in the sixth preferred embodiment, a structure that the light emitting element 2 to emit the near ultraviolet is used so as to excite the phosphors of RGB has been explained, but a structure that the light emitting element 2 to emit a blue light is used so as to excite the phosphors of RG can be also used. Further, a structure that the light emitting element 2 to emit a blue light is used so as to excite a yellow phosphor of (Ba_{0.0015}Sr_{0.951}Ca_{0.001}Fe_{0.015}Ni_{0.0015}Eu_{0.03})₃SiO₅ can be also used. Furthermore, in order to improve the color rendering property of the white color by using the yellow phosphors, (Ba_{0.67}Sr_{0.31}Eu_{0.02})₃(Mg_{0.81}Fe_{0.07}Mn_{0.2})Si₂O₈ of a red phosphor can be contained into the wavelength conversion portion, or a wavelength conversion portion containing the red phosphor can be laminated as an independent wavelength conversion portion.

### Seventh Embodiment

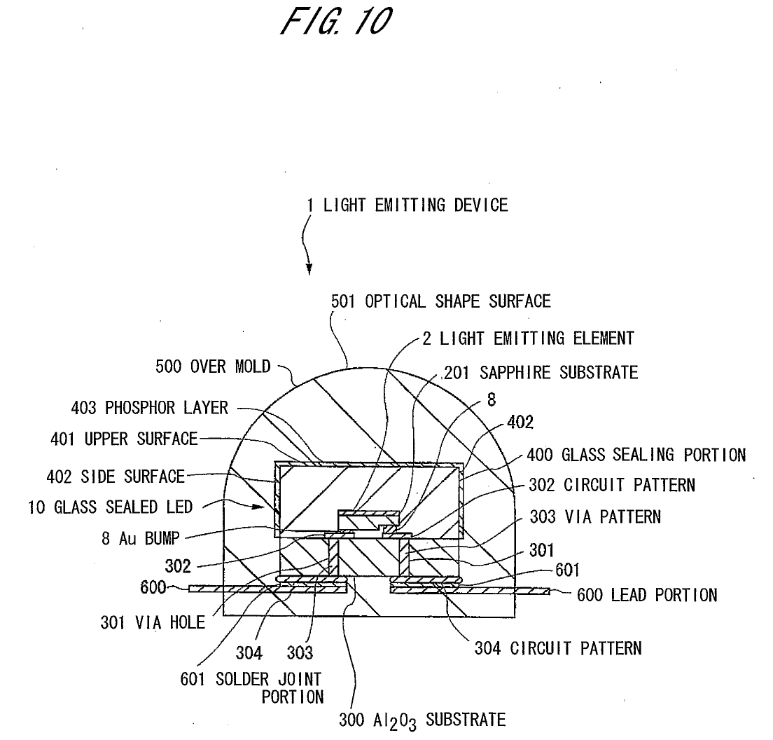

FIG. 10 is a cross-sectional view showing a light emitting device of the seventh preferred embodiment according to the invention.

The light emitting device 1 is formed by that a GaN-based semiconductor layer is formed on the sapphire substrate 201 by a crystal growth, and the light emitting device 1 comprises: a glass sealed LED 10 as an light emitting portion comprising the light emitting element 2 formed by that a phosphor layer 211 is coated on the sapphire substrate 201 flip-mounted and to be a light taking out surface, a Al₂O₃ substrate 300 as an element mounting substrate, and a glass sealing portion 400 comprising low-melting glass integrally sealing the Al₂O₃ substrate 300 mounting the light emitting element 2; a lead portion 600 comprising Cu to be connected to the glass sealed LED 10 through a solder joint portion 601; and an over mold 500 comprising a clear and colorless optically-transparent resin integrally sealing the glass sealed LED 10 and the lead portion 600.

The Al₂O₃ substrate 300 comprises via holes 301 formed by passing through from the front surface to the back surface of the substrate, a circuit pattern 302 formed on the front surface by a patterning with a thin film comprising Cu, a circuit pattern 303 similarly formed on the back surface to be a mounting surface by a patterning with the thin film of Cu, and via patterns 304 electrically connecting the circuit pattern 302 and the circuit pattern 303.

The glass sealing portion 400 is formed of phosphoric acid-based glass (Tg 390° C.) as the low-melting glass, and comprises an upper surface 401 and a side surface 402 formed by being attached to the Al₂O₃ substrate 300 containing glass by hot-press process using a die assembly (not shown) and then being cut by a dicer, and is formed in rectangular shape.

Further, the glass sealing portion 400 comprises a phosphors layer 403 comprising (Ba_{0.0015}Sr_{0.951}Ca_{0.001}Fe_{0.015}Ni_{0.0015}Eu_{0.03})₃SiO₅ of ferrous-metal-alkaline-earth-metal silicate mixed crystal phosphors on the surface. The phosphors layer 403 is a yellow phosphor to be exited by a blue light having a peak wavelength of 460 to 465 nm and to emit a yellow light having a peak wavelength of 572.5 nm.

The over mold 500 comprises acrylic resin and is formed by injection molding of acrylic resin to the light emitting device 1 of glass sealed type to which the lead portion 600 is attached. The over mold 500 comprises an optical shape surface 501 of hemispheroidal shape in the light emission direction, and the surface 501 collects the light entering the over mold 500 from the light emitting device 1 based on the optical shape and emits the light. Further, in the seventh preferred embodiment, the over mold 500 is transparent and colorless, but can be colored.

The light emitting device 1 emits a blue light having a peak wavelength of 460 to 465 nm, when an electrical power is supplied from outside through the circuit pattern 303, so as to produce an electron-positive hole recombination in the MQW (not shown) of the light emitting element 2. The blue light enters the glass sealing portion 400 through the sapphire substrate 201 to excite a yellow phosphor contained in the phosphors layer 403 formed on the surface of the portion 400, so as to produce a yellow light having a peak wavelength of 572.5 nm. The yellow light emitted as described above and the blue light emitted from the light emitting element 2 are mixed together, so as to produce a white light which passes through the over mold 500 and is emitted outward.

### Advantages of the Seventh Embodiment

According to the seventh preferred embodiment described above, a watertight construction of the glass sealed LED 10 and the lead portion 600 is more strengthened by the over mold 500, so that a high operation reliability can be ensured even in high humidity environment and a molding shape according to light collection property, emission color, mounting aspect required as component member of the glass sealed LED 10 can be provided.

Further, also in the seventh preferred embodiment, not only a blue light emitting element but also an ultraviolet light emitting element can be selected, in this case a phosphor layer containing RGB phosphor to be excited by the near ultraviolet light can be formed on the phosphors layer 403.

### Eighth Embodiment

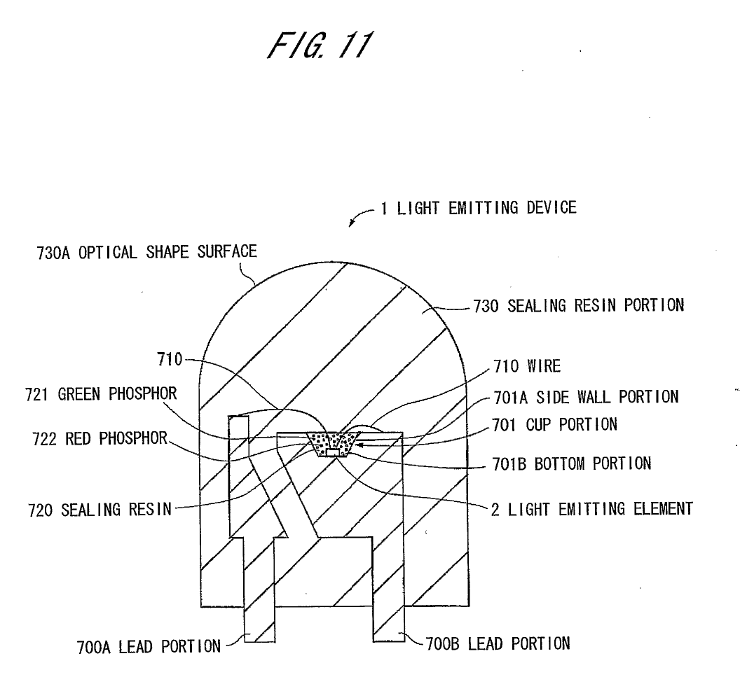

FIG. 11 is a cross-sectional view showing a light emitting device of the eighth preferred embodiment according to the invention.

The light emitting device 1 is a light emitting device of bullet shape formed by mounting the light emitting element 2 to lead portions and sealing by a sealing resin.

The light emitting device 1 comprises lead portions 700A, 700B comprising copper alloy superior to thermal conductivity, the light emitting element 2 to emit a blue light, being fixed in a cup portion 701 formed on the lead portion 700B by impression process, a wire 710 electrically connecting electrodes of the light emitting element 2 and the lead portions 700A, 700B, a sealing resin (a coating portion) 720 comprising silicone resin in which a red phosphor 721 and a green phosphor 722 to be excited by a blue light are contained, and sealing the cup portion 701 in which the light emitting element 2 is housed, and a sealing resin portion 730 comprising transparent and colorless epoxy resin, integrally sealing the lead portions 700A, 700B and the wire 710.

The cup portion 701 comprises the side wall portion 701A formed at a slant so as to reflect the blue light emitted from the light emitting element 2 in the light taking out direction, and the bottom portion 701B mounting the light emitting element 2, and is formed by impression process at press-work of the lead portion 700B. The side wall portion 701A and the bottom portion 701B can be plated with Ni in order to provide a light reflectivity.

The sealing resin portion 730 comprises an optical shape surface 730A of hemispheroidal shape at the top portion conforming to the light emission direction, collects the light emitted from the light emitting element 2 based on the optical shape, and emits the light in the emission coverage according to the optical shape. The sealing resin portion 730 can be formed by a casting mold method of housing the lead portions 700A and the lead portion 700B mounting the light emitting element 2 and wire-bonded in a die assembly of press-worked lead frame, and filing epoxy resin in the die assembly for thermal hardening.

### Advantages of the Eighth Embodiment

According to the eighth preferred embodiment described above, the red phosphor 721 and the green phosphor 722 are excited by the blue light which is an excitation wavelength band of ferrous-metal-alkaline-earth-metal silicate mixed crystal phosphors explained in the first preferred embodiment, so that also in the light emitting device of bullet shape, a white light having a good color rendering property and color reproducibility can be obtained and a structure in which the phosphor is less subject to deterioration by humidity can be obtained.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

### INDUSTRIAL APPLICABILITY

A ferrous-metal-alkaline-earth-metal silicate mixed crystal phosphor of the invention can be used as a light converter for near-ultraviolet and visible light sources, and can be applied to a light emitting device.

1. A ferrous-metal-alkaline-earth-metal mixed silicate based phosphor, wherein:
the phosphor is used in form of a single component or a mixture as a light converter for a primarily visible and/or ultraviolet light emitting device.

2. The ferrous-metal-alkaline-earth-metal mixed silicate based phosphor according to claim 1, wherein:
the phosphor comprises a rare earth element as an activator.

3. The ferrous-metal-alkaline-earth-metal mixed silicate based phosphor according to claim 2, wherein:
the rare earth element comprises europium (Eu).

4. The ferrous-metal-alkaline-earth-metal mixed silicate based phosphor according to claim 1, wherein:
the phosphor comprises a coactivator comprising a rare earth element and at least one of Mn, Bi, Sn, and Sb.

5. The ferrous-metal-alkaline-earth-metal mixed silicate based phosphor according to claim 1, wherein:
the phosphor is represented by a general formula:
M¹ₐM²_{b}M³_{c}M⁴_{d}(Si_{1-z}M⁵_{z})ₑM⁶_{f}M⁷_{g}OₕXₙ:Aₓ
where
M¹=not less than one elements of Ca, Sr, Ba and Zn,
M²=not less than one elements of Mg, Cd, Mn and Be,
M³=not less than one monovalent metal ions of group I elements in the periodic table,
M⁴=not less than one elements of Fe, Co and Ni,
M⁵=not less than one tetravalent elements of Ti, Zr, Hf and Ge,
M⁶=not less than one elements of Al, B, Ga, In, La, Sc and Y,
M⁷=not less than one elements of Sb, P, V, Nb and Ta,
X=not less than one ions of F, Cl, Br and Ito balance an electrical charge,
A=not less than one elements of Ce, Pr, Nd, Sm, Eu, Gd, Tb, Dy, Ho, Er, Tm, Yb, Lu, Bi, S, Sn and Sb,
h=a+b+c/2+d+2e+3f/2+5g/2−n/2+x,
0.5≦a≦8,
0≦b≦5,
0≦c≦4,
0<d≦2,
0<e≦10,
0≦f≦2,
0≦g≦2,
0≦n≦4,
0<x≦0.5, and
0≦z≦1.

6. The ferrous-metal-alkaline-earth-metal mixed silicate based phosphor according to claim 1, wherein:
the phosphor comprises particles a particle diameter of which is all smaller than 50 μm.

7. The ferrous-metal-alkaline-earth-metal mixed silicate based phosphor according to claim 1, wherein:
the phosphor is used alone or with an other phosphor as a light converter for an LED to emit light in a visible region of an optical spectrum.

8. A light emitting device, comprising:
a light emitting portion;
a wavelength conversion portion comprising a ferrous-metal-alkaline-earth-metal mixed silicate based phosphor to wavelength-convert a light emitted from the light emitting portion;
a power-supply portion to supply an electrical power to the light emitting portion; and
a sealing portion sealing the light emitting portion and the power-supply portion.

9. The light emitting device according to claim 8, wherein:
the light emitting portion comprises a semiconductor light emitting element, and
the ferrous-metal-alkaline-earth-metal mixed silicate based phosphor is represented by a general formula:
M¹ₐM²_{b}M^{a}_{c}M⁴_{d}(Si_{1-z}M⁵_{z})ₑM⁶_{f}M⁷_{g}OₕXₙ:Aₓ
where
M¹=not less than one elements of Ca, Sr, Ba and Zn,
M²=not less than one elements of Mg, Cd, Mn and Be,
M³=not less than one monovalent metal ions of group I elements in the periodic table,
M⁴=not less than one elements of Fe, Co and Ni,
M⁵=not less than one tetravalent elements of Ti, Zr, Hf and Ge,
M⁶=not less than one elements of Al, B, Ga, In, La, Sc and Y,
M⁷=not less than one elements of Sb, P, V, Nb and Ta,
X=not less than one ions of F, Cl, Br and Ito balance an electrical charge,
A=not less than one elements of Ce, Pr, Nd, Sm, Eu, Gd, Tb, Dy, Ho, Er, Tm, Yb, Lu, Bi, S, Sn and Sb,
h=a+b+c/2+d+2e+3f/2+5g/2−n/2+x,
0.5≦a≦8,
0≦b≦5,
0≦c≦4,
0<d≦2,
0<e≦10,
0≦f≦2,
0≦g≦2,
0≦n≦4,
0<x≦0.5, and
0≦z≦1.

10. The light emitting device according to claim 8, wherein:
the light emitting portion comprises a group III nitride-based compound semiconductor light emitting element, and
the ferrous-metal-alkaline-earth-metal mixed silicate based phosphor is represented by a general formula:
M¹ₐM²_{b}M³_{c}M⁴_{d}(Si_{1-z}M⁵_{z})ₑM⁶_{f}M⁷_{g}OₕXₙ:Aₓ
where
M¹=not less than one elements of Ca, Sr, Ba and Zn,
M²=not less than one elements of Mg, Cd, Mn and Be,
M³=not less than one monovalent metal ions of group I elements in the periodic table,
M⁴=not less than one elements of Fe, Co and Ni,
M⁵=not less than one tetravalent elements of Ti, Zr, Hf and Ge,
M⁶=not less than one elements of Al, B, Ga, In, La, Sc and Y,
M⁷=not less than one elements of Sb, P, V, Nb and Ta,
X=not less than one ions of F, Cl, Br and Ito balance an electrical charge,
A=not less than one elements of Ce, Pr, Nd, Sm, Eu, Gd, Tb, Dy, Ho, Er, Tm, Yb, Lu, Bi, S, Sn and Sb,
h=a+b+c/2+d+2e+3f/2+5g/2−n/2+x,
0.5≦a≦8,
0≦b≦5,
0≦c≦4,
0<d≦2,
0<e≦10,
0≦f≦2,
0≦g≦2,
0≦n≦4,
0<x≦0.5, and
0≦z≦1.

11. The light emitting device according to claim 8, wherein:
the wavelength conversion portion is mixed with a light transmitting material and is disposed in the sealing portion in form of a layer.

12. The light emitting device according to claim 8, wherein:
the wavelength conversion portion is mixed with a light transmitting material and is disposed in a vicinity of the light emitting portion.

13. The light emitting device according to claim 8, wherein:
the light emitting portion comprises:
a group III nitride-based compound semiconductor light emitting element;
an element mounting substrate mounting the light emitting element; and
a glass sealing portion integrally sealing the light emitting element and the element mounting substrate.

14. The light emitting device according to claim 13, wherein:
the wavelength conversion portion is integrally disposed on a surface of the glass sealing portion.

15. The light emitting device according to claim 9, wherein:
the semiconductor light emitting element comprises a sapphire substrate shaped optically.

16. The ferrous-metal-alkaline-earth-metal mixed silicate based phosphor according to claim 2, wherein:
the phosphor is represented by a general formula:
M¹ₐM²_{b}M³_{c}M⁴_{d}(Si_{1-z}M⁵_{z})ₑM⁶_{f}M⁷_{g}OₕXₙ:Aₓ
where
M¹=not less than one elements of Ca, Sr, Ba and Zn,
M²=not less than one elements of Mg, Cd, Mn and Be,
M³=not less than one monovalent metal ions of group I elements in the periodic table,
M⁴=not less than one elements of Fe, Co and Ni,
M⁵=not less than one tetravalent elements of Ti, Zr, Hf and Ge,
M⁶=not less than one elements of Al, B, Ga, In, La, Sc and Y,
M⁷=not less than one elements of Sb, P, V, Nb and Ta,
X=not less than one ions of F, Cl, Br and Ito balance an electrical charge,
A=not less than one elements of Ce, Pr, Nd, Sm, Eu, Gd, Tb, Dy, Ho, Er, Tm, Yb, Lu, Bi, S, Sn and Sb,
h=a+b+c/2+d+2e+3f/2+5g/2−n/2+x,
0.5≦a≦8,
0≦b≦5,
0≦c≦4,
0<d≦2,
0<e≦10,
0≦f≦2,
0≦g≦2,
0≦n≦4,
0<x≦0.5, and
0≦z≦1.

17. The ferrous-metal-alkaline-earth-metal mixed silicate based phosphor according to claim 3, wherein:
the phosphor is represented by a general formula:
M¹ₐM²_{b}M³_{c}M⁴_{d}(Si_{1-z}M⁵_{z})ₑM⁶_{f}M⁷_{g}OₕXₙ:Aₓ
where
M¹=not less than one elements of Ca, Sr, Ba and Zn,
M²=not less than one elements of Mg, Cd, Mn and Be,
M³=not less than one monovalent metal ions of group I elements in the periodic table,
M⁴=not less than one elements of Fe, Co and Ni,
M⁵=not less than one tetravalent elements of Ti, Zr, Hf and Ge,
M⁶=not less than one elements of Al, B, Ga, In, La, Sc and Y,
M⁷=not less than one elements of Sb, P, V, Nb and Ta,
X=not less than one ions of F, Cl, Br and Ito balance an electrical charge,
A=not less than one elements of Ce, Pr, Nd, Sm, Eu, Gd, Tb, Dy, Ho, Er, Tm, Yb, Lu, Bi, S, Sn and Sb,
h=a+b+c/2+d+2e+3f/2+5g/2−n/2+x,
0.5≦a≦8,
0≦b≦5,
0≦c≦4,
0<d≦2,
0<e≦10,
0≦f≦2,
0≦g≦2,
0≦n≦4,
0<x≦0.5, and
0≦z≦1.

18. The ferrous-metal-alkaline-earth-metal mixed silicate based phosphor according to claim 4, wherein:
the phosphor is represented by a general formula:
M¹ₐM²_{b}M³_{c}M⁴_{d}(Si_{1-z}M⁵_{z})ₑM⁶_{f}M⁷_{g}OₕXₙ:Aₓ
where
M¹=not less than one elements of Ca, Sr, Ba and Zn,
M²=not less than one elements of Mg, Cd, Mn and Be,
M³=not less than one monovalent metal ions of group I elements in the periodic table,
M⁴=not less than one elements of Fe, Co and Ni,
M⁵=not less than one tetravalent elements of Ti, Zr, Hf and Ge,
M⁶=not less than one elements of Al, B, Ga, In, La, Sc and Y,
M⁷=not less than one elements of Sb, P, V, Nb and Ta,
X=not less than one ions of F, Cl, Br and Ito balance an electrical charge,
A=not less than one elements of Ce, Pr, Nd, Sm, Eu, Gd, Tb, Dy, Ho, Er, Tm, Yb, Lu, Bi, S, Sn and Sb,
h=a+b+c/2+d+2e+3f/2+5g/2−n/2+x,
0.5≦a≦8,
0≦b≦5,
0≦c≦4,
0<d≦2,
0<e≦10,
0≦f≦2,
0≦g≦2,
0≦n≦4,
0<x≦0.5, and
0≦z≦1.

19. The ferrous-metal-alkaline-earth-metal mixed silicate based phosphor according to claim 2, wherein:
the phosphor comprises particles a particle diameter of which is all smaller than 50 μm.

20. The ferrous-metal-alkaline-earth-metal mixed silicate based phosphor according to claim 3, wherein:
the phosphor comprises particles a particle diameter of which is all smaller than 50 μm.
